(19) United States
(12) Patent Application Publication
(10) Pub. No.: US 2025/0391697 A1
(43) Pub. Date: Dec. 25, 2025

(54) SUPPORT TAPE AND METHOD OF MANUFACTURING SEMICONDUCTOR DEVICE BY USING THE SAME

(71) Applicant: Samsung Electronics Co., Ltd., Suwon-si (KR)

(72) Inventor: Hyung Jun Kim, Suwon-si (KR)

(21) Appl. No.: 19/024,323

(22) Filed: Jan. 16, 2025

(30) Foreign Application Priority Data
Jun. 21, 2024 (KR) 10-2024-0081376

(51) Int. Cl. H01L 21/683; H01L 21/56; H01L 23/00

(52) U.S. Cl. CPC H01L 21/6836; H01L 21/565; H01L 24/81; H01L 24/83; H01L 2221/68322; H01L 2221/68386; H01L 2224/81815; H01L 2224/83862; H01L 2924/37001

(57) ABSTRACT

A support tape and a semiconductor device manufacturing method are provided. The semiconductor device manufacturing support tape comprising: a base layer including a first aerogel layer; and an adhesive layer on a top surface of the first aerogel layer, wherein a bottom surface of the first aerogel layer is externally exposed.

### CROSS-REFERENCE TO RELATED APPLICATION

This application is based on and claims priority under 35 U.S.C. § 119 to Korean Patent Application No. 10-2024-0081376, filed Jun. 21, 2024, in the Korean Intellectual Property Office, the disclosure of which is incorporated by reference herein in its entirety.

### BACKGROUND

The inventive concept relates to a support tape and a method of manufacturing a semiconductor device by using the same, and more particularly, to a support tape including an aerogel layer.

With the development of electronics industry, electronic products with a smaller weight, a smaller size, a higher speed, and higher performance may be provided at a low price. In manufacturing a semiconductor package, a wafer-level preliminary semiconductor package may be manufactured. A preliminary semiconductor package may be sawed to form a plurality of semiconductor packages. A carrier substrate may be used in a process of manufacturing the preliminary semiconductor package.

### SUMMARY

The inventive concept relates to a support tape with improved thermal insulation properties and high elongation yield and a method of manufacturing a semiconductor device using the same.

The inventive concept relates to a support tape and a method of manufacturing a semiconductor device. According to an aspect of the inventive concept, there is provided a semiconductor device manufacturing support tape comprising: a base layer including a first aerogel layer; and an adhesive layer on a top surface of the first aerogel layer, wherein a bottom surface of the first aerogel layer is externally exposed.

According to another aspect of the inventive concept, there is provided a semiconductor device manufacturing support tape including a first aerogel layer; and an adhesive layer on a top surface of the first aerogel layer, wherein a bottom surface of the first aerogel layer is externally exposed, wherein the first aerogel layer has a thermal conductivity of about 0.00001 W/mK to about 0.03 W/mK, wherein the first aerogel layer has an elongation yield of about 50% to about 1,500%, wherein the first aerogel layer has density of about 500 g/m³ to about 1,500 g/m³, wherein the first aerogel layer has pores therein, and wherein the first aerogel layer has a porosity of about 90 vol % to about 99.8 vol %.

According to another aspect of the inventive concept, there is provided a semiconductor device manufacturing method comprising: providing a support tape including a base layer and an adhesive layer; providing a preliminary semiconductor device on the adhesive layer; performing a processing step on the preliminary semiconductor device to form a semiconductor device; and separating the semiconductor device from the support tape, wherein the base layer comprises a first aerogel layer.

### BRIEF DESCRIPTION OF THE DRAWINGS

The embodiments will be more clearly understood from the following detailed description taken in conjunction with the accompanying drawings in which:

FIG. 1A is a cross-sectional view illustrating a support tape according to some embodiments;

FIG. 1B is a cross-sectional view illustrating a support tape according to some embodiments;

FIG. 1C is a cross-sectional view illustrating a support tape according to some embodiments;

FIG. 1D is a cross-sectional view illustrating a support tape according to some embodiments;

FIG. 1E is a cross-sectional view illustrating a support tape according to some embodiments;

FIGS. 2A to 2E are views illustrating a method of manufacturing a semiconductor device according to some embodiments; and

FIGS. 3A to 3M are views illustrating a method of manufacturing a semiconductor package according to some embodiments.

### DETAILED DESCRIPTION OF THE EMBODIMENTS

In the current specification, like reference numerals refer to like elements. Hereinafter, a support layer according to some embodiments, a method of manufacturing a semiconductor device using the same, and a method of manufacturing a semiconductor package using the same will be described. It should be understood that the same parts utilized in different embodiments may have the same part number. This does not mean that the two embodiments are linked, but instead refers to a part in the new embodiment that is essentially identical to the same part in the first embodiment in terms of shape, size, orientation, composition, manufacture, etc.

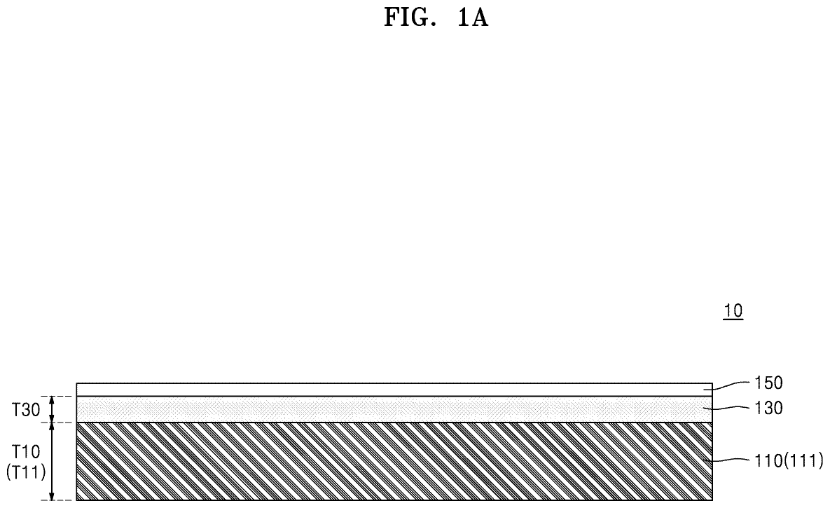

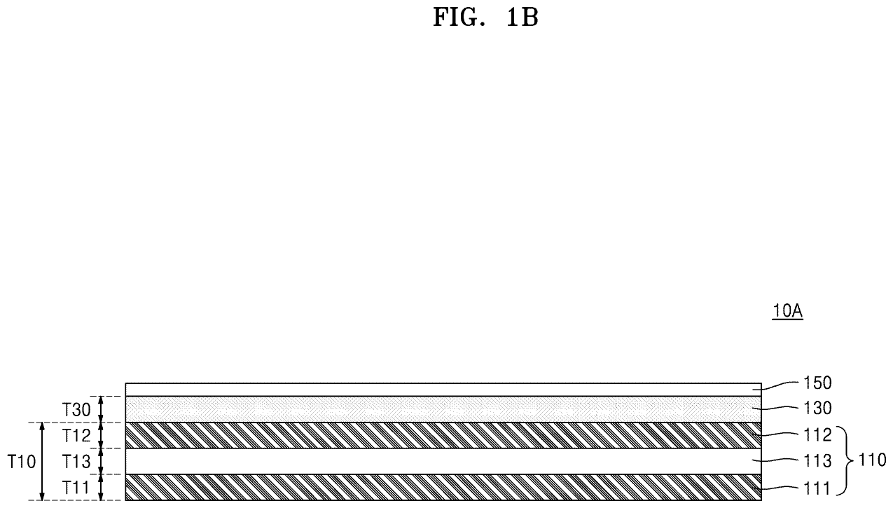

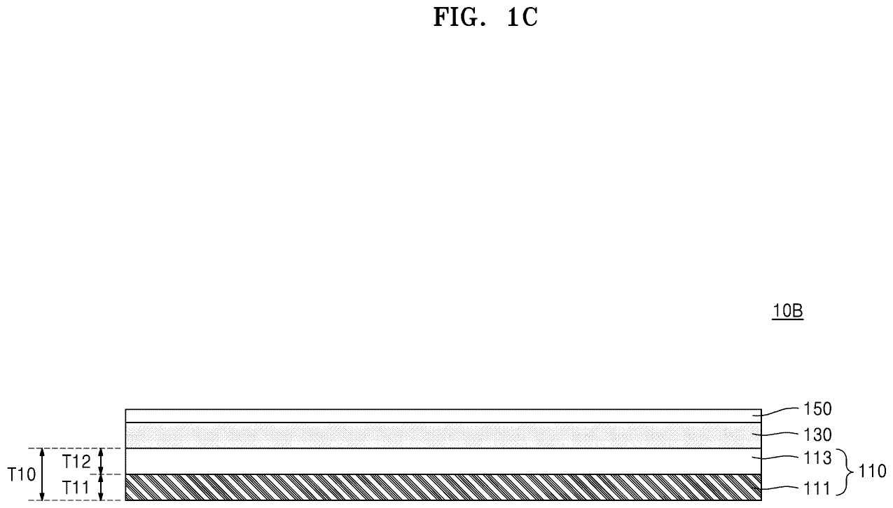

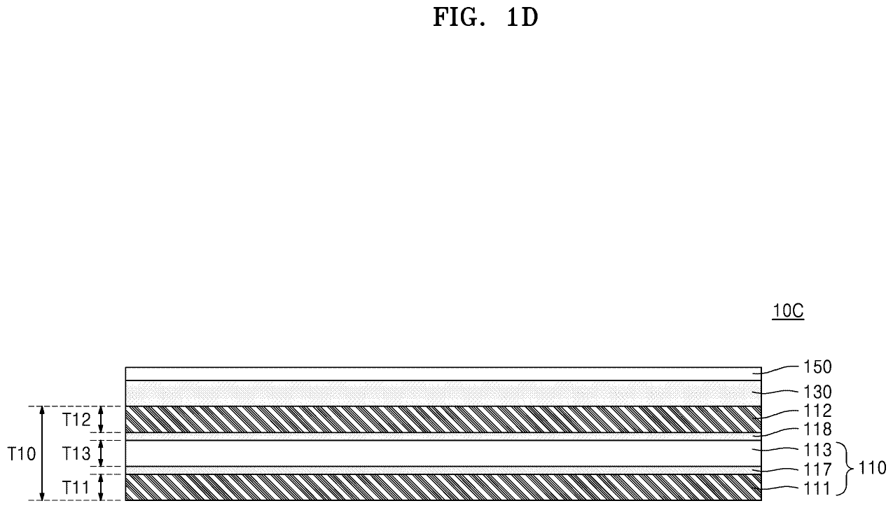

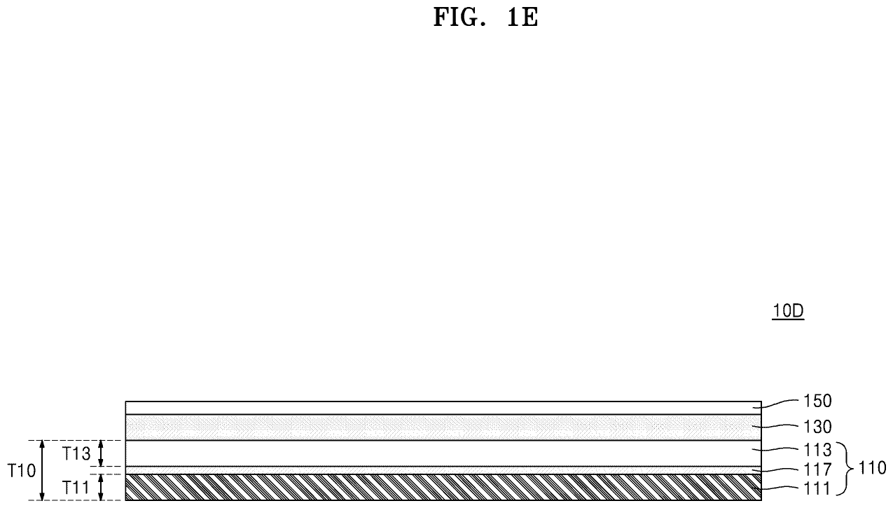

FIG. 1A is a cross-sectional view illustrating a support tape 10 according to embodiments.

Referring to FIG. 1A, the support tape 10 may be provided. The support tape 10 may include a semiconductor device manufacturing support tape or a support tape for a semiconductor process. The support tape 10 may be used in a semiconductor manufacturing process using a wafer support system. For example, the support tape 10 may support a wafer-level preliminary semiconductor package in a semiconductor package manufacturing process. As another example, the support tape 10 may support a wafer-level semiconductor substrate. The semiconductor substrate may include a preliminary semiconductor substrate for manufacturing a semiconductor chip.

The support tape 10 may include a base layer 110 and an adhesive layer 130. The base layer 110 may include aerogel. For example, the base layer 110 may include a first aerogel layer 111, and the first aerogel layer 111 may include aerogel. For example, the aerogel may include organic aerogel, inorganic aerogel, and/or organic-inorganic hybrid aerogel. Organic aerogel may include polymer aerogel. When the aerogel includes organic-inorganic hybrid aerogel, the aerogel may include inorganic aerogel and organic aerogel surrounding the inorganic aerogel. In this case, the organic aerogel may include polyolefin (PO), polyimide (PI), gelatin, cellulose, and/or a combination thereof.

The first aerogel layer 111 may have a relatively high elongation yield. For example, the first aerogel layer 111 may have an elongation yield of about 50% to about 1,500%. Accordingly, the elongation yield of the first support tape 10 may be increased.

The first aerogel layer 111 may have high thermal insulation properties. For example, the first aerogel layer 111 may have a thermal conductivity of about 0.00001 W/mK to about 0.03 W/mK. Because the thermal conductivity of the first aerogel layer 111 satisfies the above range, the base layer 110 may exhibit improved thermal insulation properties.

The first aerogel layer 111 may have pores. The first aerogel layer 111 may have a porosity of about 90 vol % to about 99.8 vol %. The porosity of the first aerogel layer 111 may refer to a volume ratio of pores to the total volume of the first aerogel layer 111. The porosity of the first aerogel layer 111 satisfies the above conditions, so that the first aerogel layer 111 may exhibit improved thermal insulation properties and may have a high elongation yield. The first aerogel layer 111 may have density of about 500 g/m³ to about 1,500 g/m³. The density of the first aerogel layer 111 satisfies the above conditions, so that the first aerogel layer 111 may exhibit improved thermal insulation properties and may have a high elongation yield.

The base layer 110 may have a thickness T10 of about 25 μm to about 300 μm. The thickness T10 of the base layer 110 may be equal to the thickness T11 of the first aerogel layer 111. When the thickness T10 of the base layer 110 is less than 25 μm, it may be difficult for the support tape 10 to support a preliminary semiconductor device. In addition, it may be more difficult to manufacture the first aerogel layer 111. The preliminary semiconductor device may include the wafer-level preliminary semiconductor package or the wafer-level semiconductor substrate. When the thickness T10 of the base layer 110 is greater than 300 μm, the support tape 10 may weigh more. Accordingly, it may be difficult to smoothly transport the support tape 10.

According to an embodiment, a top surface of the base layer 110 may correspond to a top surface of the first aerogel layer 111. In other words, the first aerogel layer 111 may correspond to the uppermost layer of the base layer 110. A bottom surface of the base layer 110 may correspond to a bottom surface of the first aerogel layer 111. In other words, the first aerogel layer 111 may correspond to the lowermost layer of the base layer 110. Also. the first aerogel layer 111 may correspond to the lowermost layer of the support tape 10. For example, other components or other layers may not be provided on the bottom surface of the first aerogel layer 111. The bottom surface of the first aerogel layer 111 may be externally exposed. A bottom surface of the support tape 10 may include the bottom surface of the first aerogel layer 111.

The adhesive layer 130 may be provided on the first aerogel layer 111. The adhesive layer 130 may be directly attached onto the top surface of the first aerogel layer 111. The adhesive layer 130 may include, for example, a pressure sensitive adhesive layer. The adhesive layer 130 may include a photocurable material. At this time, the adhesive layer 130 may be in an uncured state. For example, the adhesive layer 130 may include an acrylate-based material such as acrylate polymer. The adhesive layer 130 may further include at least one of a cross-linking agent, a photocuring agent, and an additive. The additive may further include at least one of an ultraviolet (UV) absorber and a coating leveling agent. The UV absorber may include a material having an aromatic ring or a conjugate structure. For example, the UV absorber may include benzophenone and/or a derivative thereof. The coating leveling agent may include a silicon-based surfactant. For example, the adhesive layer 130 may have a thickness T30 of about 5 μm to about 50 μm.

The support tape 10 may further include a cover film 150. The cover film 150 may be provided on a top surface of the adhesive layer 130 to cover the top surface of the adhesive layer 130. The cover film 150 may include a release film or a protective film.

The cover film 150 may include an organic material such as polymer. For example, the cover film 150 may include polyethylene terephthalate (PET), polyolefin (PO), poly(vinyl alcohol) (PVA), poly(1-naphthylamine) (PNA), polyether ketone (PEEK), and/or a mixture thereof. The cover film 150 may prevent the top surface of the adhesive layer 130 from being contaminated by external foreign substances. The cover film 150 may protect the top surface of the adhesive layer 130 from external stress. The physical stress may be an external shock, but is not limited thereto. Prior to use of the support tape 10, the cover film 150 may be removed.

FIG. 1B is a cross-sectional view illustrating a support tape 10A according to embodiments. Hereinafter, repetitive descriptions are omitted.

Referring to FIG. 1B, a support tape 10A may include a base layer 110 and an adhesive layer 130. The base layer 110 may include a polymer layer 113 and a second aerogel layer 112 in addition to the first aerogel layer 111. The material, density, thermal conductivity, elongation yield, and porosity of the first aerogel layer 111 may be substantially the same as those described in the example of FIG. 1A. However, the first aerogel layer 111 may have a thickness T11 of about 25 μm to about 100 μm. Because the thickness T11 of the first aerogel layer 111 is greater than 25 μm, the first aerogel layer 111 may be easily manufactured. Because the thickness T11 of the first aerogel layer 111 is less than 100 μm, the support tape 10A may be easily transported. A bottom surface of the first aerogel layer 111 may be externally exposed.

The polymer layer 113 may be provided on a top surface of the first aerogel layer 111. The polymer layer 113 may be provided between, for example, the first aerogel layer 111 and the second aerogel layer 112. Accordingly, the first aerogel layer 111, the polymer layer 113, and the second aerogel layer 112 may form a sandwich structure. The polymer layer 113 may include polyethylene terephthalate (PET), polybutylene terephthalate (PBT), polyolefin (PO), and/or a combination thereof. PO may include polyethylene (PE) or polypropylene (PP). However, the inventive concept is not limited thereto. The polymer layer 113 may have a thickness T13 of about 25 μm to about 100 μm. Because the thickness T13 of the polymer layer 113 is greater than 25 μm, the polymer layer 113 may be easily manufactured. Because the thickness T13 of the polymer layer 113 is less than 100 μm, the support tape 10A may be easily transported.

The second aerogel layer 112 may be provided on a top surface of the polymer layer 113. The second aerogel layer 112 may be between the polymer layer 113 and the adhesive layer 130. The second aerogel layer 112 may include aerogel. For example, aerogel may include organic aerogel, inorganic aerogel, and/or organic-inorganic hybrid aerogel.

The second aerogel layer 112 may have a relatively high elongation yield. For example, the second aerogel layer 112 may have an elongation yield of about 50% to about 1,500%. Accordingly, the elongation yield of the first support tape 10A may be increased.

The second aerogel layer 112 may have improved thermal insulation properties. For example, the second aerogel layer 112 may have a thermal conductivity of about 0.00001 W/mK to about 0.03 W/mK. Because the thermal conductivity of the second aerogel layer 112 satisfies the above range, the base layer 110 may exhibit improved thermal insulation properties.

The second aerogel layer 112 may have pores. Porosity of the second aerogel layer 112 may be about 90 vol % to about 99.8 vol %. The porosity of the second aerogel layer 112 may refer to a volume ratio of pores to the total volume of the second aerogel layer 112. The porosity of the second aerogel layer 112 satisfies the above conditions, so that the second aerogel layer 112 may exhibit improved thermal insulation properties and may have a high elongation yield. The second aerogel layer 112 may have density of about 500 g/m³ to about 1,500 g/m³. The density of the second aerogel layer 112 satisfies the above conditions, so that the second aerogel layer 112 may exhibit improved thermal insulation properties and may have a high elongation yield.

The second aerogel layer 112 may have a thickness T12 of about 25 μm to about 100 μm. Because the thickness T12 of the second aerogel layer 112 is greater than 25 μm, the second aerogel layer 112 may be easily manufactured. Because the thickness T12 of the second aerogel layer 112 is less than 100 μm, the support tape 10A may be easily transported. The thickness T10 of the base layer 110 may be equal to the sum of the thickness T11 of the first aerogel layer 111, the thickness T13 of the polymer layer 113, and the thickness T12 of the second aerogel layer 112.

The thermal conductivity of the base layer 110 may be 0.001 W/mK to 0.005 W/mK. Accordingly, the base layer 110 may have improved thermal insulation properties.

The adhesive layer 130 may be provided on a top surface of the second aerogel layer 112 to cover the top surface of the second aerogel layer 112. The adhesive layer 130 may have a thickness T30 that is the same as that described in the example of FIG. 1A.

The support tape 10A may further include a cover film 150. The adhesive layer 130 and the cover film 150 may be substantially the same as those described in the example of FIG. 1A.

FIG. 1C is a cross-sectional view illustrating a support tape 10B according to embodiments.

Referring to FIG. 1C, the support tape 10B may include a base layer 110 and an adhesive layer 130. The base layer 110 may include a first aerogel layer 111 and a polymer layer 113. However, the base layer 110 may not include the second aerogel layer 112 of FIG. 1B. The adhesive layer 130 may be directly provided on a top surface of the polymer layer 113 to cover the top surface of the polymer layer 113. The support tape 10B may further include a cover film 150.

The base layer 110 may have a thickness T10 that is equal to the sum of the thickness T11 of the first aerogel layer 111 and the thickness T13 of the polymer layer 113. A range of the thickness T10 of the base layer 110 may satisfy the conditions described in the example of FIG. 1A.

FIG. 1D is a cross-sectional view illustrating a support tape 10C according to embodiments.

Referring to FIG. 1D, the support tape 10C may include a base layer 110 and an adhesive layer 130. The base layer 110 may further include a first adhesive film 117 and a second adhesive film 118 in addition to a first aerogel layer 111, a polymer layer 113, and a second aerogel layer 112.

The first adhesive film 117 may be between the first aerogel layer 111 and the polymer layer 113. The first aerogel layer 111 may be attached to the polymer layer 113 via the first adhesive film 117. The first adhesive film 117 may include an organic adhesive material such as polymer. The thickness T17 of the first adhesive film 117 may be less than the thickness T11 of the first aerogel layer 111, the thickness T13 of the polymer layer 113, and the thickness T12 of the second aerogel layer 112. In other words, the thickness T17 of the first adhesive film 117 may be less than any of the thicknesses of the first aerogel layer 111, the polymer layer 113, or the second aerogel layer 112 individually and/or less than the sum of the thicknesses of the first aerogel layer 111, the polymer layer 113, and the second aerogel layer 112. The thickness T17 of the first adhesive film 117 may be about 0.01 μm to about 5 μm.

The second adhesive film 118 may be between the second aerogel layer 112 and the polymer layer 113. The second aerogel layer 112 may be attached to the polymer layer 113 via the second adhesive film 118. The second adhesive film 118 may include an organic adhesive material such as polymer. The thickness T18 of the second adhesive film 118 may be less than the thickness T11 of the first aerogel layer 111, the thickness T13 of the polymer layer 113, and the thickness T12 of the second aerogel layer 112. In other words, the thickness T18 of the second adhesive film 118 may be less than any of the thicknesses of the first aerogel layer 111, the polymer layer 112, or the second aerogel layer 112 individually and/or less than the sum of the thicknesses of the first aerogel layer 111, the polymer layer 112, and the second aerogel layer 112. The thickness T18 of the second adhesive film 118 may be about 0.01 μm to about 5 μm.

The thermal conductivity of the base layer 110 may be 0.001 W/mK to 0.005 W/mK. Accordingly, the base layer 110 may have improved thermal insulation properties. The thickness T10 of the base layer 110 may be equal to the sum of the thickness T11 of the first aerogel layer 111, the thickness T17 of the first adhesive film 117, the thickness T13 of the polymer layer 113, the thickness T18 of the second adhesive film 118, and the thickness T12 of the second aerogel layer 112. A range of the thickness T10 of the base layer 110 may satisfy the conditions described in the example of FIG. 1A. In some embodiments, as shown in FIG. 1E, the second adhesive film 118 and the second aerogel layer 112 may be omitted.

The support tape 10C may further include a cover film 150.

FIG. 1E is a cross-sectional view illustrating a support tape 10D according to embodiments.

Referring to FIG. 1E, the support tape 10D may include a base layer 110 and an adhesive layer 130. The support tape 10D may further include a cover film 150. The base layer 110 may further include a first adhesive film 117 in addition to a first aerogel layer 111 and a polymer layer 113.

The first adhesive film 117 may be between the first aerogel layer 111 and the polymer layer 113. The first aerogel layer 111 may be attached to the polymer layer 113 via the first adhesive film 117. The material and the thickness T17 of the first adhesive film 117 may be the same as those described in the example of the first adhesive film 117 of FIG. 1D. The thickness T17 of the first adhesive film 117 may be less than the thickness T11 of the first aerogel layer 111 and the thickness T13 of the polymer layer 113.

The thermal conductivity of the base layer 110 may be 0.001 W/mK to 0.005 W/mK. Accordingly, the base layer 110 may have improved thermal insulation properties. The thickness T10 of the base layer 110 may be equal to the sum of the thickness T11 of the first aerogel layer 111, the thickness T17 of the first adhesive film 117, and the thickness T13 of the polymer layer 113. A range of the thickness T10 of the base layer 110 may satisfy the conditions described in the example of FIG. 1A.

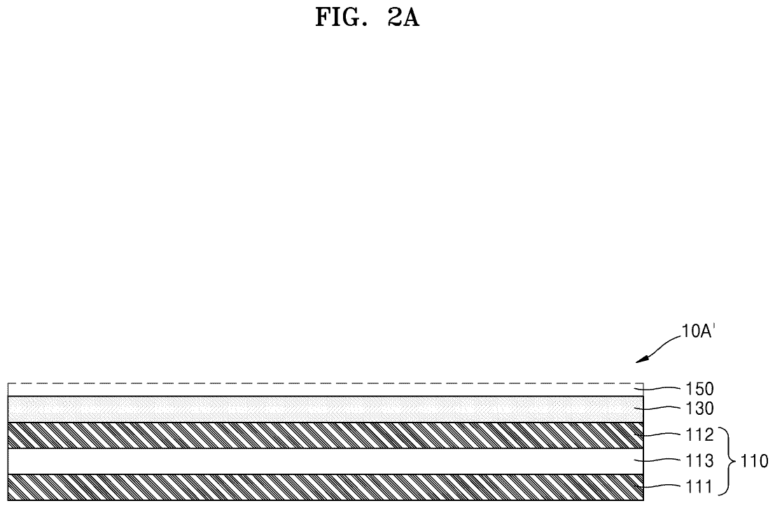

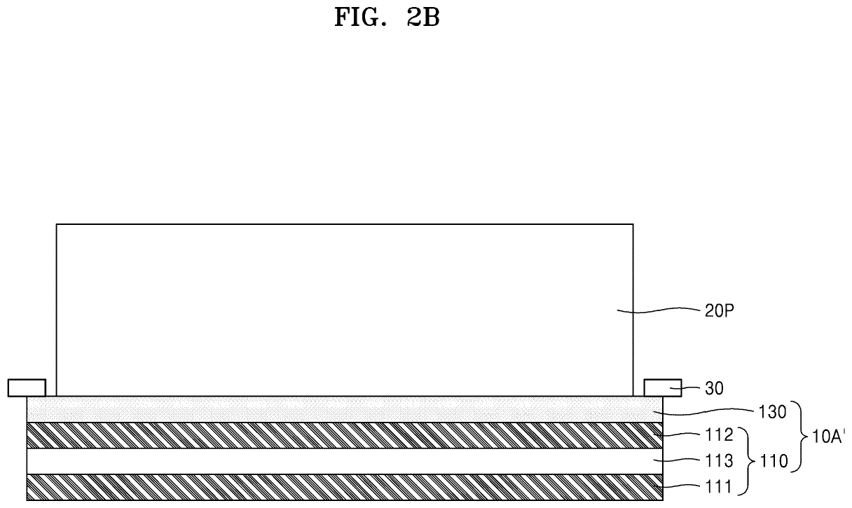

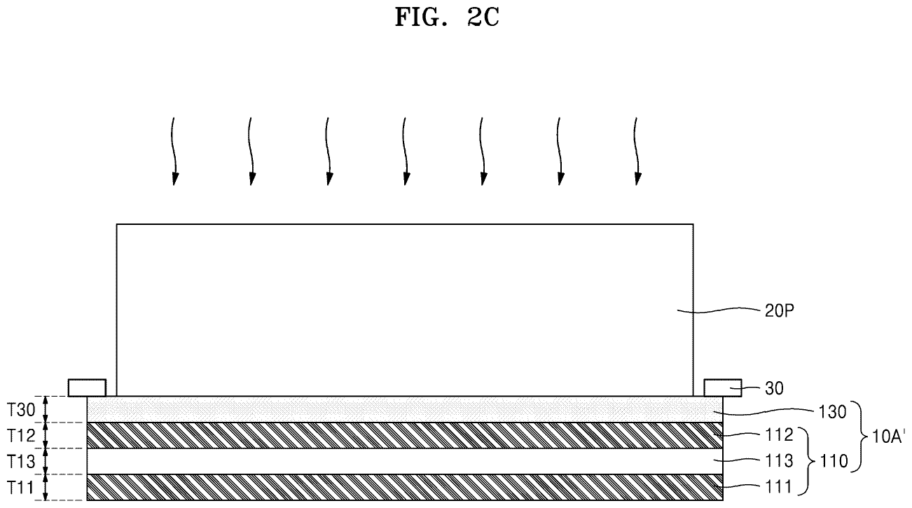

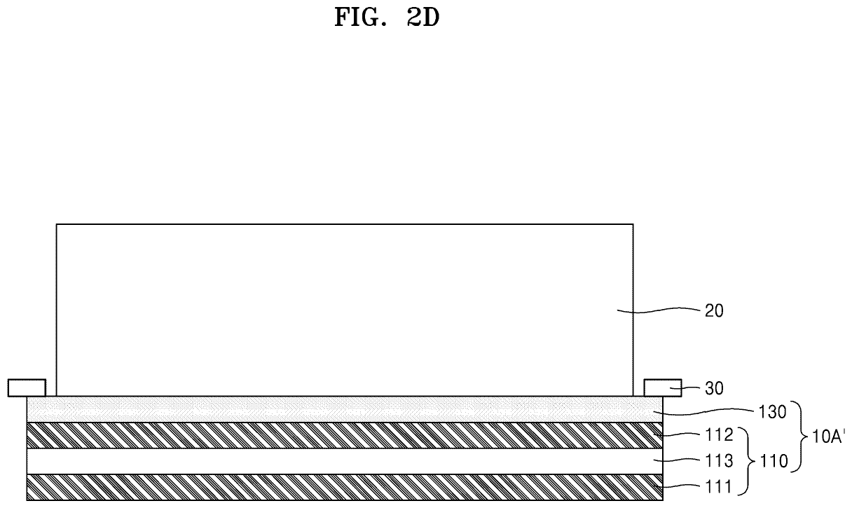

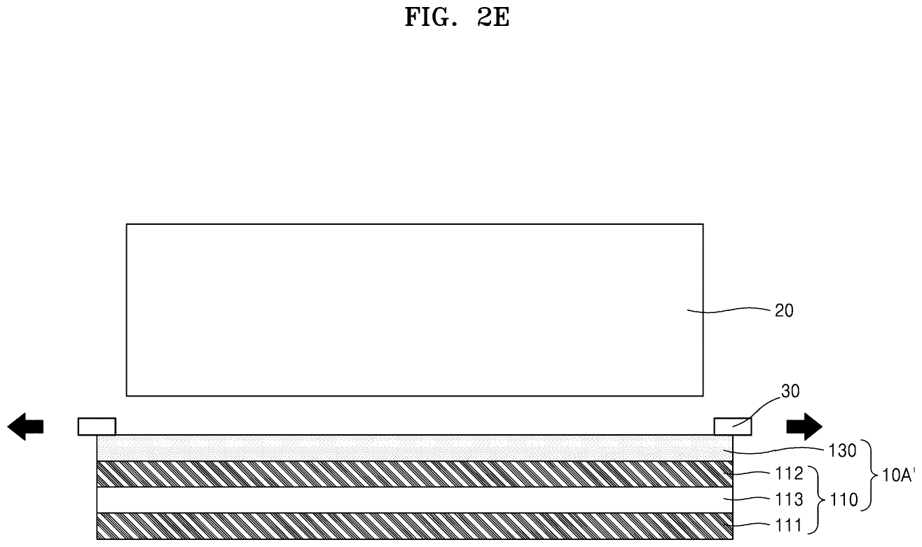

FIGS. 2A to 2E are views illustrating a method of manufacturing a semiconductor device according to embodiments. Hereinafter, repetitive descriptions are omitted.

Referring to FIG. 2A, a support tape 10A′ may be provided. The support tape 10A described in the example of FIG. 1B may be used as the support tape 10A′. For example, the support tape 10A′ may include a base layer 110, an adhesive layer 130, and a cover film 150. The base layer 110 may include a first aerogel layer 111, a polymer layer 113, and a second aerogel layer 112. Alternatively, the support tape 10 of FIG. 1A, the support tape 10B of FIG. 1C, the support tape 10C of FIG. 1D, or the support tape 10D of FIG. 1E may be used as the support tape 10A′.

As indicated by a dotted line, the cover film 150 may be removed to expose a top surface of the adhesive layer 130. The cover film 150 may be removed by a physical method or a mechanical method. The cover film 150 may prevent contamination of or damage to the adhesive layer 130 during transport and storage of the support tape 10A′.

Referring to FIG. 2B, a preliminary semiconductor device 20P may be provided on the support tape 10A′. As an example, providing the preliminary semiconductor device 20P may include attaching the preliminary semiconductor device 20P onto the top surface of the adhesive layer 130. As another example, providing the preliminary semiconductor device 20P may include forming the preliminary semiconductor device 20P on the support tape 10A′.

The preliminary semiconductor device 20P may include a wafer-level semiconductor device. For example, the preliminary semiconductor device 20P may include a wafer-level semiconductor package or a wafer-level semiconductor substrate. The semiconductor substrate may include a plurality of dies or chips. A circuit layer may be provided on bottom surfaces of the plurality of dies or chips. The circuit layer may include transistors and wires. The wires may be electrically connected to the transistors. The circuit layer may include a back-end off-line (BEOL) and a front-end off-line (FEOL). Through vias may be further provided in the plurality of dies or chips. Alternatively, the through vias may be formed in the plurality of dies or chips in a processing step to be described later.

Prior to the arrangement of the preliminary semiconductor device 20P, a frame 30 may be attached onto a top surface of an edge region of the support tape 10A′. The frame 30 may include a ring frame. For example, the frame 30 may have a ring shape or a closed loop shape in plain view. The preliminary semiconductor device 20P may be apart from the frame 30.

Referring to FIGS. 2C and 2D in turn, a processing step may be performed on the preliminary semiconductor device 20P to manufacture a semiconductor device 20. The processing step may include a plurality of subprocesses. For example, the processing step may include at least one of a first processing subprocess, a heat treatment subprocess, and a second processing subprocess. The first processing subprocess may include at least one of a semiconductor chip arrangement operation, a redistribution substrate formation operation, a molding layer application operation, an underfill layer injection operation, a conductive post formation operation, and/or a through vias formation operation.

The heat treatment subprocess may include a solder ball reflow operation, a molding layer curing operation, or an underfill layer curing operation. The molding layer curing operation may include a thermal curing suboperation. The underfill layer curing operation may include a thermal curing suboperation. The heat treatment subprocess may be performed at about 150° C. to about 280° C. After the first processing subprocess, the heat treatment subprocess may be performed. However, the inventive concept is not limited thereto.

When the support tape 10A′is deformed during the heat treatment subprocess, stress may be applied to the preliminary semiconductor device 20P. Specifically, deformation of the support tape 10A′ may include shrinkage of the base layer 110 or stretching of the base layer 110. Stress may occur due to deformation of the base layer 110. The stress may be applied to the preliminary semiconductor device 20P via the adhesive layer 130. In this case, damage to the preliminary semiconductor device 20P may occur. When the support tape 10A′ is deformed during the heat treatment subprocess, the preliminary semiconductor device 20P may be undesirably separated from the support tape 10A′. When the preliminary semiconductor device 20P is separated from the support tape 10A′, it may be difficult to support the preliminary semiconductor device 20P during the heat treatment subprocess.

According to embodiments, the base layer 110 includes a first aerogel layer 111 and a second aerogel layer 112 and thus may have improved thermal insulation properties. Accordingly, deformation of the base layer 110 may be prevented during the heat treatment subprocess. Damage to the preliminary semiconductor device 20P may be prevented during the heat treatment subprocess. Because the first aerogel layer 111 and the second aerogel layer 112 have thermal conductivities within the range described above, deformation of the base layer 110 may be prevented during the heat treatment subprocess. In addition, the preliminary semiconductor device 20P may be stably supported by the support tape 10A′ during the heat treatment subprocess.

Because the thermal conductivity of the base layer 110 satisfies a range of about 0.001 W/mK to about 0.005 W/mK, deformation of the support tape 10A′ may be prevented during the heat treatment subprocess. Yield of a process of manufacturing the semiconductor device 20 may be increased. In other words, the reduction in deformation of the support tape 10A′ results in fewer manufacturing defects and thereby a greater output of semiconductor devices 20.

The preliminary semiconductor device 20P may be provided on a top surface of the support tape 10A′. A bottom surface of the support tape 10A′ may face the top surface of the support tape 10A′ and may include a bottom surface of the first aerogel layer 111. Because the lowermost layer of the support tape 10A′ includes the first aerogel layer 111 having a thermal conductivity of about 0.00001 W/mK to about 0.03 W/mK, the support tape 10A′ may have improved thermal insulation properties.

When the first aerogel layer 111 or the second aerogel layer 112 has an excessively large elongation yield (for example, an elongation yield of more than 1,500%), the first aerogel layer 111 or the second aerogel layer 112 may be deformed during the heat treatment subprocess. According to embodiments, because each of the first aerogel layer 111 and the second aerogel layer 112 has an elongation yield of 1,500% or less, deformation of the support tape 10A′ may be prevented.

After the heat treatment subprocess, the second processing subprocess may be further performed. For example, when the preliminary semiconductor device 20P includes a wafer-level preliminary semiconductor package, the second processing subprocess may include a preliminary semiconductor package sawing operation. A plurality of semiconductor packages separated side by side from one another may be formed by the preliminary semiconductor package sawing operation. As another example, when the preliminary semiconductor device 20P includes a wafer-level semiconductor substrate, the second processing subprocess may include a semiconductor substrate dicing operation. A plurality of semiconductor chips separated side by side from one another may be formed by the semiconductor substrate dicing operation.

Alternatively, at least one of the first processing subprocess and the second processing subprocess may be omitted.

As a result of the processing step, the semiconductor device 20 illustrated in FIG. 2D may be manufactured.

Referring to FIG. 2E, the semiconductor device 20 may be separated from the support tape 10A′. Separating the semiconductor device 20 from the support tape 10A′ may be performed by a process of peeling the support tape 10A′. For example, separating the semiconductor device 20 from the support tape 10A′ may include curing the adhesive layer 130 by irradiating it and applying tensile force to the support tape 10A′. For example, light may be used to irradiate the support tape 10A′. In other words, the radiation used to irradiate the support tape 10A′ may be light, meaning the wavelength of the radiation used to irradiate the support tape 10A′ may be within or close to the visible range of the electromagnetic spectrum. The light may include ultraviolet (UV) rays. For example, light may be transmitted to the adhesive layer 130. The adhesive layer 130 may be cured by light. Adhesive force between the semiconductor device 20 and the cured adhesive layer 130 may be reduced. For example, adhesive force between the adhesive layer 130 and the semiconductor device 20 after irradiating light may be smaller than adhesive force between the adhesive layer 130 and the semiconductor device 20 before irradiating light.

Thereafter, tensile force may be applied to the support tape 10A′. For example, tensile force may be applied to the support tape 10A′ by pulling the frame 30 outward. Because the support tape 10A′ is stretched laterally, the semiconductor device 20 may be separated from the support tape 10A′. According to embodiments, because the support tape 10A′ has a relatively high elongation yield, the semiconductor device 20 may be more easily separated from the support tape 10A′. For example, because each of the first aerogel layer 111 and the second aerogel layer 112 has an elongation yield of 50% or more, the semiconductor device 20 may be easily separated from the support tape 10A′. Thereafter, the semiconductor device 20 may be picked up. Pick-up characteristics of the semiconductor device 20 may be improved. In addition, because the support tape 10A′ has a relatively high elongation yield, the semiconductor device 20 may be easily separated from the support tape 10A′. After the semiconductor device 20 is separated from the support tape 10A′, no residue of the adhesive layer 130 may remain on a bottom surface 21 of the semiconductor device 20. The bottom surface 21 of the semiconductor device 20 may be attached to the adhesive layer 130.

For example, when the semiconductor device 20 includes a plurality of semiconductor packages, each of the plurality of semiconductor packages may be picked up. The plurality of semiconductor packages may be separated from the support tape 10A′ by the pickup process. As another example, when the semiconductor device 20 includes a plurality of semiconductor chips, each of the plurality of semiconductor chips may be picked up. Accordingly, each of the plurality of semiconductor chips may be separated from the support tape 10A′. As another example, when the semiconductor device 20 includes a wafer-level preliminary semiconductor package or a wafer-level semiconductor substrate, the preliminary semiconductor package or the semiconductor substrate may be picked up. Accordingly, the support tape 10A′ may be separated from the preliminary semiconductor package or the semiconductor substrate.

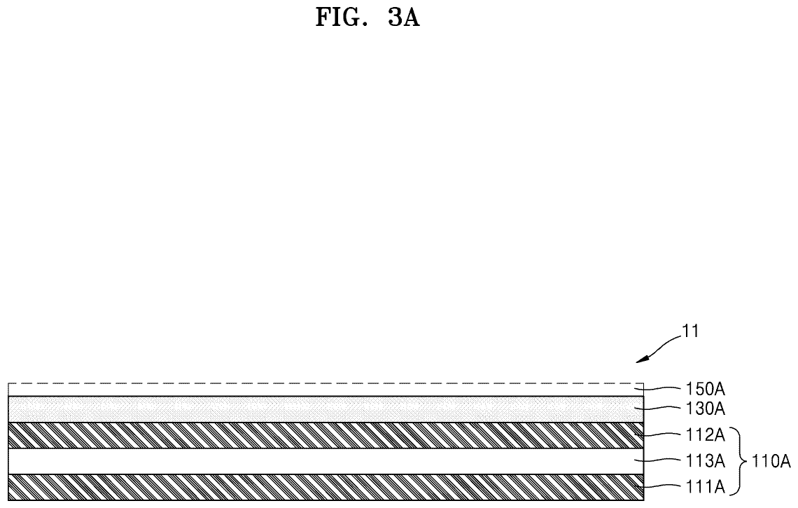

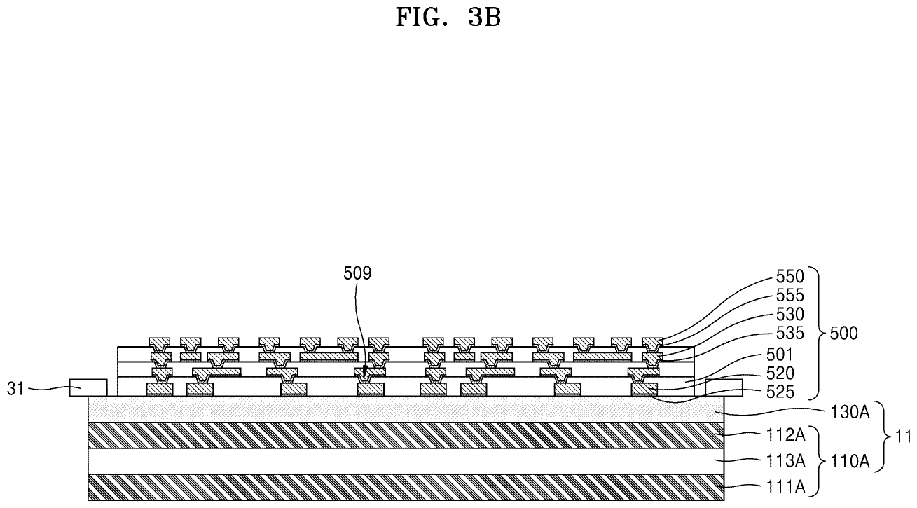

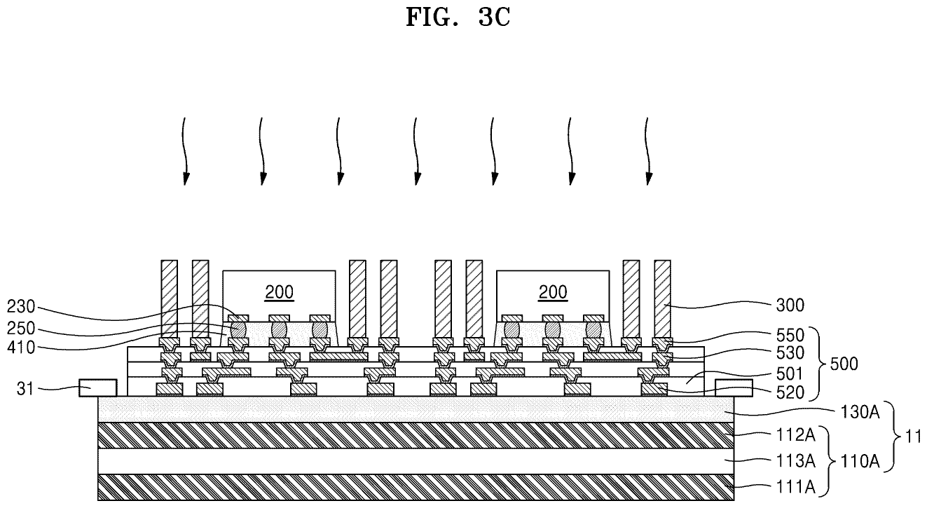

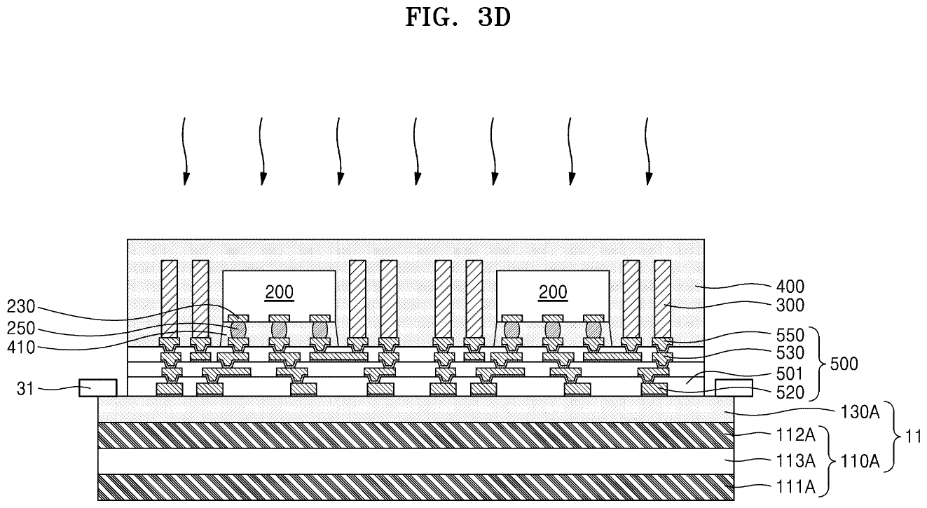

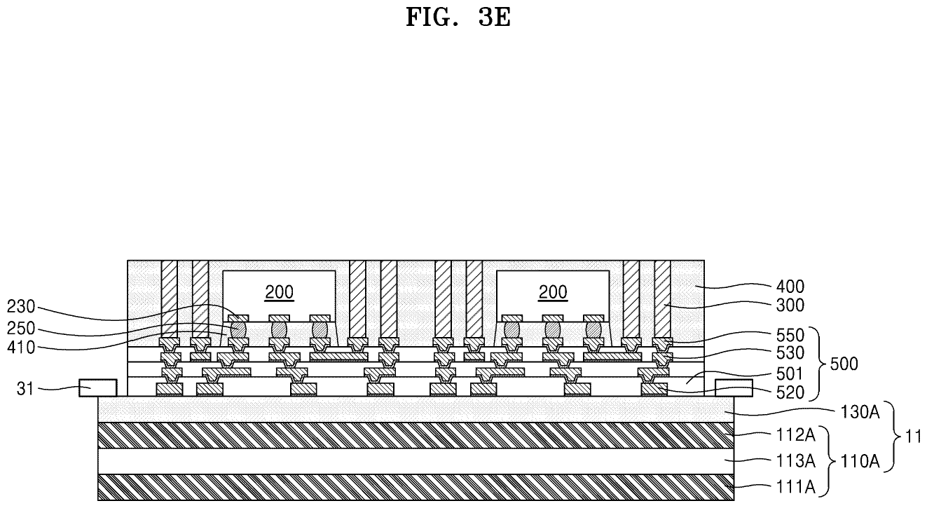

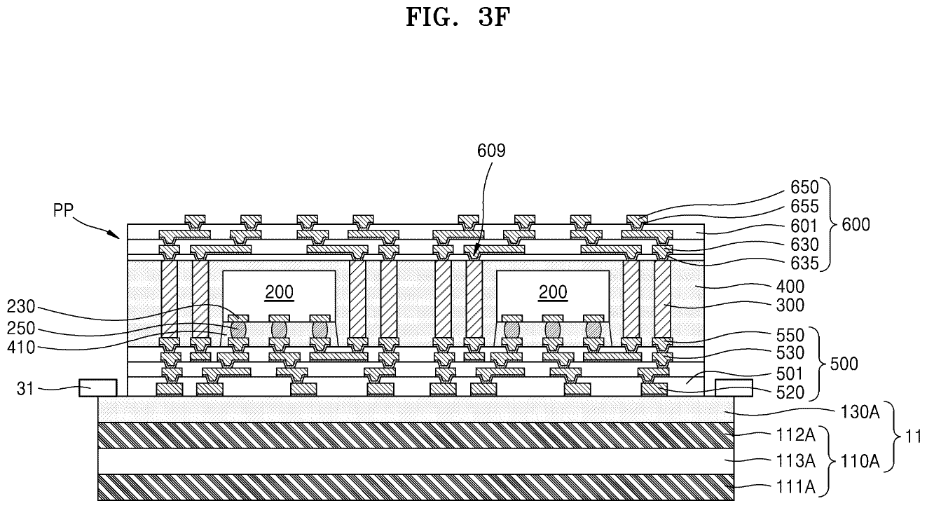

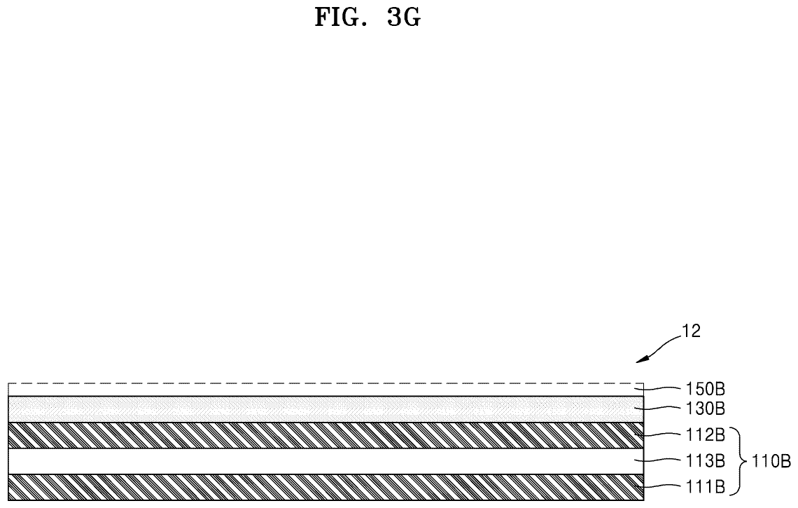

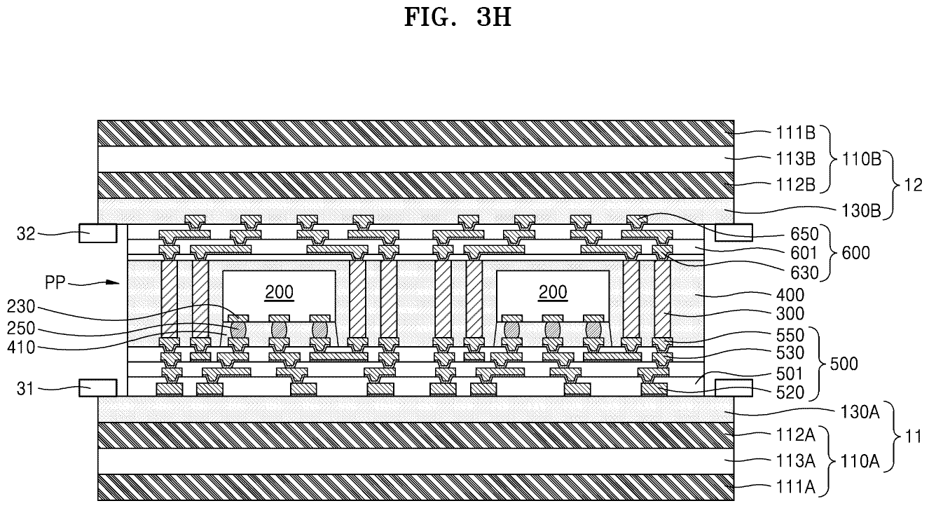

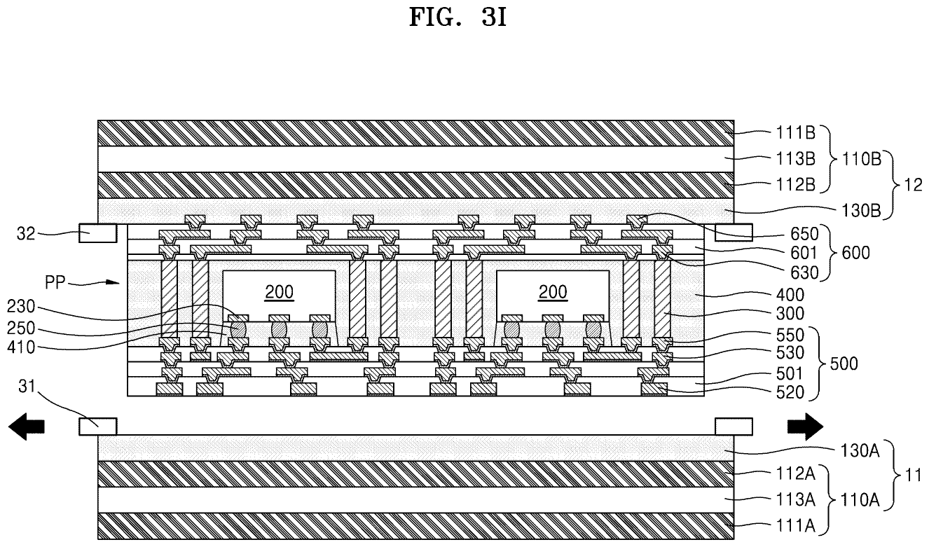

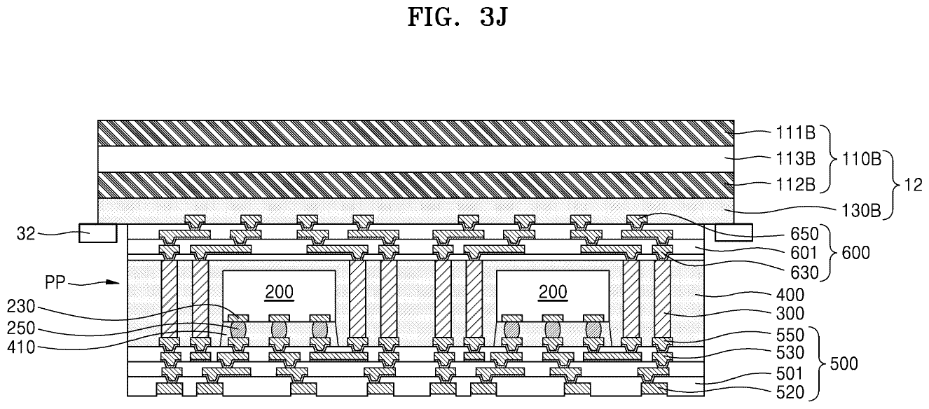

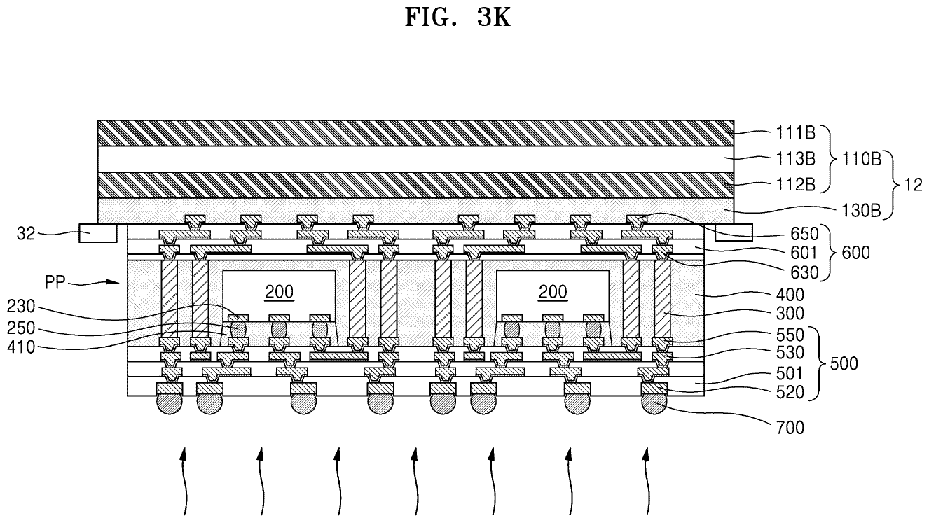

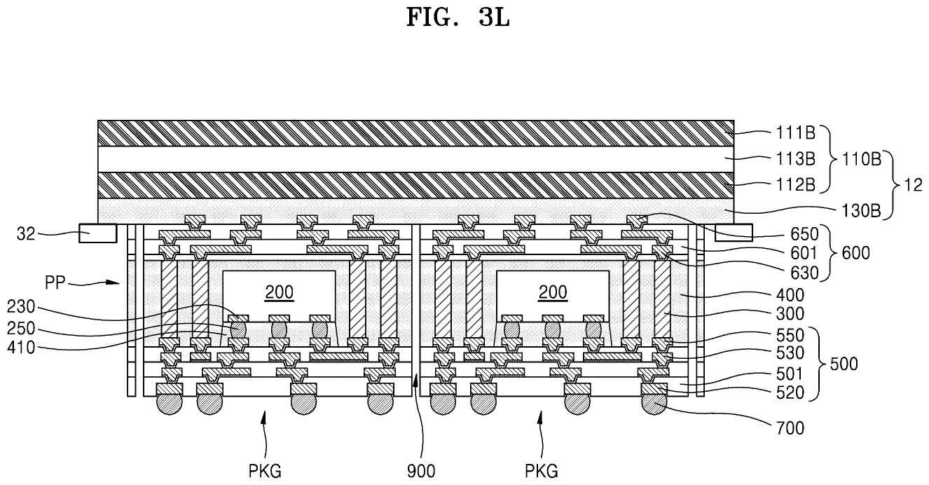

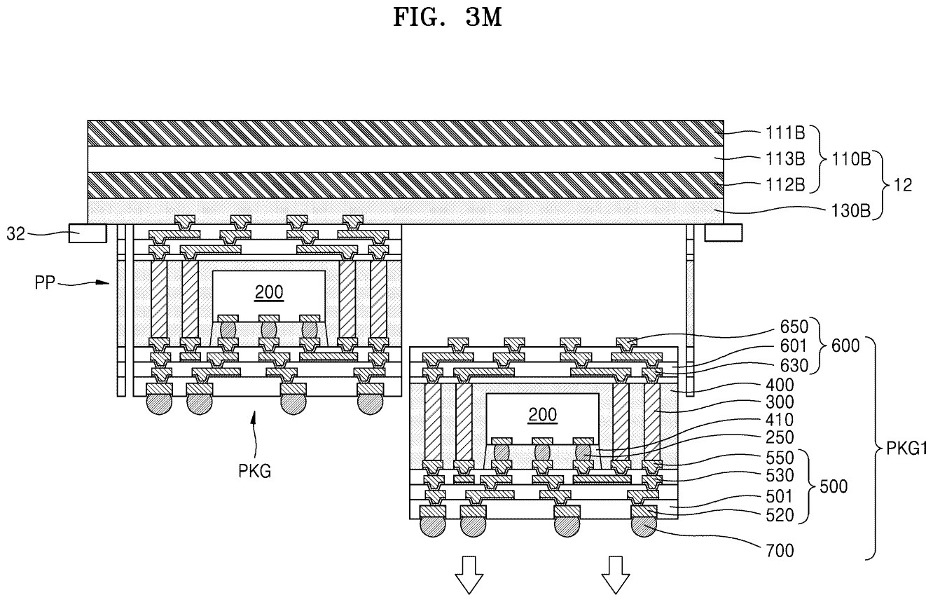

FIGS. 3A to 3M are views illustrating a method of manufacturing a semiconductor package according to embodiments. Hereinafter, repetitive descriptions are omitted.

Referring to FIG. 3A, a first support tape 11 may be provided. For example, the support tape 10A described in the example of FIG. 1B may be used as the first support tape 11. For example, the first support tape 11 may include a first base layer 110A, a first adhesive layer 130A, and a first cover film 150A. The first base layer 110A may include a first aerogel layer 111A, a first polymer layer 113A, and a second aerogel layer 112A. The first base layer 110A, the first adhesive layer 130A, and the first cover film 150A may be substantially the same as the base layer 110, the adhesive layer 130, and the cover film 150 described in the example of FIG. 1B. The first aerogel layer 111A, the first polymer layer 113A, and the second aerogel layer 112A may be substantially the same as the first aerogel layer 111, the polymer layer 113, and the second aerogel layer 112 described in the example of FIG. 1B.

Alternatively, the support tape 10 of FIG. 1A, the support tape 10B of FIG. 1C, the support tape 10C of FIG. 1D, or the support tape 10D of FIG. 1E may be used as the first support tape 11.

As indicated by a dotted line, the first cover film 150A may be removed to expose a top surface of the first adhesive layer 130A. The first cover film 150A may be removed after the first support tape 11 is transported.

Referring to FIG. 3B, a first frame 31 may be arranged on a top surface of an edge region of the first support tape 11. For example, the first frame 31 may be arranged on the top surface of the first adhesive layer 130A.

A first redistribution substrate 500 may be formed on a top surface of the first support tape 11. The first redistribution substrate 500 may be formed, for example, on the top surface of the first adhesive layer 130A. For example, under bump seed patterns 525, under bump patterns 520, a first insulating layer 501, first seed patterns 535, first redistribution patterns 530, first seed pads 555, and first redistribution pads 550 may be formed on the first support tape 11 to manufacture the first redistribution substrate 500.

According to embodiments, the under bump seed patterns 525 may be formed on the top surface of the first adhesive layer 130A. The under bump patterns 520 may be formed by an electroplating process using the under bump seed patterns 525 as electrodes. The first insulating layer 501 may be formed on the top surface of the first adhesive layer 130A to cover sidewalls and top surfaces of the under bump patterns 520. First openings 509 may be formed in the first insulating layer 501 to expose the under bump patterns 520. The first seed patterns 535 may be formed in the first openings 509 and on a top surface of the first insulating layer 501. The first redistribution patterns 530 may be formed on the first seed patterns 535 by performing an electroplating process using the first seed patterns 535 as electrodes.

Thereafter, the processes of forming the first insulating layer 501, forming the first seed patterns 535, and forming the first redistribution patterns 530 may be repeatedly performed. Accordingly, stacked first insulating layers 501 and stacked first redistribution patterns 530 may be formed. The first seed patterns 535 may be formed on bottom surfaces of the first redistribution patterns 530, respectively. Some of the first redistribution patterns 530 may vertically overlap one another and may be electrically connected to one another. Others of the first redistribution patterns 530 may be apart from one another and may be electrically isolated from one another.

The first redistribution pads 550 may be formed in and on the uppermost first insulating layer 501 to be connected to the first redistribution patterns 530. Before forming the first redistribution pads 550, the first seed pads 555 may be formed. An electroplating process using the first seed pads 555 as electrodes may be performed to form the first redistribution pads 550. Accordingly, the first redistribution substrate 500 may be manufactured. The first redistribution substrate 500 may include first insulating layers 501, under bump seed patterns 525, under bump patterns 520, first seed patterns 535, first redistribution patterns 530, first seed pads 555, and first redistribution pads 550.

The first insulating layers 501 may include a photo-imageable dielectric (PID) material. The PID material may include, for example, polymer such as photosensitive polyimide, polybenzoxazole, phenol-based polymer, and/or benzocyclobutene-based polymer. For example, the first insulating layers 501 may include the same material. An interface between adjacent first insulating layers 501 may not be distinguished. The number of first insulating layers 501 may vary.

The under bump patterns 520, the first redistribution patterns 530, and the first redistribution pads 550 may include a metal such as copper (Cu). The under bump seed patterns 525, the first seed patterns 535, and the first seed pads 555 may include a conductive seed material. The conductive seed material may include a metal different from that of the under bump patterns 520 and the first redistribution patterns 530. The conductive seed material may include titanium (Ti), Ti—Cu, or an alloy thereof.

At least one of the first redistribution pads 550 may be connected to the corresponding under bump pattern 520 via the first redistribution patterns 530 electrically connected thereto. Because the first redistribution patterns 530 are provided, one or more of the first redistribution pads 550 may not be vertically aligned with the under bump pattern 520 electrically connected thereto. Accordingly, the arrangement of the first redistribution pads 550 may be designed more freely. The number of first redistribution patterns 530 stacked between the under bump patterns 520 and the first redistribution pads 550 is not limited to that illustrated and may vary.

In the current specification, being electrically connected to the first redistribution substrate 500 may include being electrically connected to at least one of the first redistribution patterns 530.

Referring to FIG. 3C, conductive posts 300 may be formed on a top surface of the first redistribution substrate 500. The conductive posts 300 may be formed on the corresponding first redistribution pads 550 to be electrically connected to the first redistribution pads 550. The conductive posts 300 may have a pillar shape. However, the inventive concept is not limited thereto. As an example, forming the conductive posts 300 may include performing an electroplating process. The conductive posts 300 may include, for example, a metal material such as Cu.

A plurality of semiconductor chips 200 may be mounted on the first redistribution substrate 500. For example, the plurality of semiconductor chips 200 may be arranged to be apart from one another. The semiconductor chip 200 may be one of a logic chip, a buffer chip, and a memory chip. Each of the plurality of semiconductor chips 200 may include chip pads 230 on a bottom surface thereof. Bumps 250 may be provided on bottom surfaces of the chip pads 230. The bumps 250 may be provided on top surfaces of the corresponding first redistribution pads 550.

Mounting the plurality of semiconductor chips 200 may include performing a reflow process of the bumps 250. The reflow process of the bumps 250 may correspond to the heat treatment subprocess described in the example of FIG. 2C. The reflow process of the bumps 250 may be performed at about 150° C. to about 280° C. The first base layer 110A may include the first aerogel layer 111A and the second aerogel layer 112A to prevent deformation of the first support tape 11 during the reflow process of the bumps 250. As a result of the reflow process, the bumps 250 may be bonded to the corresponding first redistribution pads 550 and may be electrically connected to the first redistribution pads 550. Accordingly, the plurality of semiconductor chips 200 may be electrically connected to the first redistribution substrate 500. The bumps 250 may include solder balls, and the solder balls may include a solder material. The solder material may include, for example, tin (Sn), silver (Ag), zinc (Zn), and/or an alloy thereof. The bumps 250 may further include pillar patterns.

Underfill layers 410 may be formed in gap regions between the first redistribution substrate 500 and the plurality of semiconductor chips 200 to cover sidewalls of the corresponding bumps 250. The underfill layers 410 may include insulating polymer such as epoxy polymer. Hereinafter, for simplicity, a single underfill layer 410 will be described.

The forming process of the underfill layer 410 may include an injection process of the underfill layer 410 and a thermal curing process of the underfill layer 410. The thermal curing process of the underfill layer 410 may correspond to the heat treatment subprocess described in the example of FIG. 2C. The thermal curing process may be performed at about 150° C. to about 280° C. The first base layer 110A may include the first aerogel layer 111A and the second aerogel layer 112A to prevent deformation of the first support tape 11 during the thermal curing process.

Referring to FIG. 3D, a molding layer 400 may be formed on the top surface of the first redistribution substrate 500 to cover the plurality of semiconductor chips 200 and the conductive posts 300. The molding layer 400 may cover sidewalls and top surfaces of the conductive posts 300. Forming the molding layer 400 may include applying insulating polymer on the first redistribution substrate 500 and performing a curing process on the insulating polymer. The curing process of the molding layer 400 may correspond to the heat treatment subprocess described in the example of FIG. 2C. The curing process may be performed at about 150° C. to about 280° C. The first base layer 110A may include the first aerogel layer 111A and the second aerogel layer 112A to prevent deformation of the first support tape 11 during the thermal curing process.

The molding layer 400 may include insulating polymer such as an epoxy-based molding compound. The molding layer 400 may include insulating polymer different from that of the underfill layer 410. As another example, the underfill layer 410 may be omitted, and the molding layer 400 may be further extended into gap regions between the first redistribution substrate 500 and the plurality of semiconductor chips 200.

Referring to FIG. 3E, a grinding process is performed on the molding layer 400 to remove an upper portion of the molding layer 400. The grinding process may include a chemical mechanical polishing subprocess. After the grinding process is completed, a top surface of the molding layer 400 may be coplanar with the top surfaces of the conductive posts 300.

Referring to FIG. 3F, a second redistribution substrate 600 may be formed on the molding layer 400 and the conductive posts 300. According to embodiments, a second insulating layer 601 may be formed on the top surface of the molding layer 400. Second holes 609 may be formed in the second insulating layer 601 to expose the top surfaces of the conductive posts 300, respectively. Second seed patterns 635 may be conformally formed in the second holes 609 and on a top surface of the second insulating layer 601. Second redistribution patterns 630 may be formed in the second holes 609 and on the top surface of the second insulating layer 601 to cover the second seed patterns 635.

The method of forming the second seed patterns 635 and the second redistribution patterns 630 may be the same as or similar to that described in the example of forming the first seed patterns 535 and the first redistribution patterns 530 of FIG. 3B. The process of forming the second insulating layer 601, the process of forming the second seed patterns 635, and the process of forming the second redistribution patterns 630 may be repeatedly performed. Accordingly, a plurality of stacked second insulating layers 601, a plurality of second seed patterns 635, and a plurality of stacked second redistribution patterns 630 may be formed. The second insulating layers 601 may include a PID material. For example, the second redistribution patterns 630 may include a metal such as Cu. The second seed patterns 635 may include a metal different from that of the second redistribution patterns 630. For example, the second seed patterns 635 may include a conductive seed material.

The second redistribution pads 650 may be formed in the uppermost second insulating layer 601 and on a top surface of the uppermost second insulating layer 601. For example, the second redistribution pads 650 may include a metal such as Cu. Before forming the second redistribution pads 650, second seed pads 655 may be formed. The second seed pads 655 may include a metal different from that of the second redistribution pads 650. The second seed pads 655 may include a conductive seed material. The second redistribution pads 650 may be formed by an electroplating process using the second seed pads 655 as electrodes. Accordingly, the second redistribution substrate 600 may be manufactured. The second redistribution substrate 600 may include the plurality of second insulating layers 601, the second seed patterns 635, the second redistribution patterns 630, the second seed pads 655, and the second redistribution pads 650.

The second redistribution substrate 600 may be electrically connected to the conductive posts 300. In the current specification, being electrically connected to the second redistribution substrate 600 may include being electrically connected to at least one of the second redistribution patterns 630.

The preliminary semiconductor package PP may be manufactured by the examples described so far. The preliminary semiconductor package PP may include the first redistribution substrate 500, the plurality of semiconductor chips 200, the bumps 250, the underfill layer 410, the conductive posts 300, the molding layer 400, and the second redistribution substrate 600. The preliminary semiconductor package PP may include a wafer-level package.

Referring to FIG. 3G, a second support tape 12 may be provided. For example, the support tape 10A described in the example of FIG. 1B may be used as the second support tape 12. For example, the second support tape 12 may include a second base layer 110B, a second adhesive layer 130B, and a second cover film 150B. The second base layer 110B may include a first aerogel layer 111B, a second polymer layer 113B, and a second aerogel layer 112B. The second base layer 110B, the second adhesive layer 130B, and the second cover film 150B may be substantially the same as the base layer 110, the adhesive layer 130, and the cover film 150 described in the example of FIG. 1B. The first aerogel layer 111B, the second polymer layer 113B, and the second aerogel layer 112B may be substantially the same as the first aerogel layer 111, the polymer layer 113, and the second aerogel layer 112 described in the example of FIG. 1B.

Alternatively, the support tape 10 of FIG. 1A, the support tape 10B of FIG. 1C, the support tape 10C of FIG. 1D, or the support tape 10D of FIG. 1E may be used as the first support tape 11.

As indicated by a dotted line, the second cover film 150B may be removed to expose a top surface of the second adhesive layer 130B.

Referring to FIG. 3H, the second support tape 12 may be turned over so that the second adhesive layer 130B faces downward. A second frame 32 may be arranged on a bottom surface of an edge region of the second support tape 12. For example, the second frame 32 may be arranged on a bottom surface of the second adhesive layer 130B. The bottom surface of the second adhesive layer 130B of FIG. 3H may correspond to the top surface of the second adhesive layer 130B of FIG. 3G.

The second support tape 12 may be provided on the second redistribution substrate 600. For example, the second adhesive layer 130B may be attached onto a top surface of the second redistribution substrate 600. For example, the second adhesive layer 130B may be attached onto the uppermost second insulating layer 601 and the second redistribution pads 650.

Referring to FIG. 3I, the first support tape 11 may be separated from the preliminary semiconductor package PP. For example, the first support tape 11 may be separated from the first redistribution substrate 500 to expose a bottom surface of the second redistribution substrate 600. Separating the first support tape 11 from the first redistribution substrate 500 may include curing the first adhesive layer 130A by irradiating it and applying tensile force to the first support tape 11. For example, light may be used to irradiate the first adhesive layer 130A to cure the first adhesive layer 130A. In other words, the radiation used to irradiate the first adhesive layer 130A may be light, meaning the wavelength of the radiation used to irradiate the first adhesive layer 130A may be within or close to the visible range of the electromagnetic spectrum. Adhesive force between the semiconductor device 20 and the cured first adhesive layer 130A may be reduced.

Tensile force may be applied to the first support tape 11 by pulling the first frame 31 outward. Because the first support tape 11 is stretched laterally, the first support tape 11 may be separated from the preliminary semiconductor package PP. Because each of the first aerogel layer 111 and the second aerogel layer 112 has a high elongation yield, the first support tape 11 may be easily separated. After the first support tape 11 is separated, a bottom surface of the first redistribution substrate 500 may be exposed. Because each of the first aerogel layer 111 and the second aerogel layer 112 has a high elongation yield, the first support tape 11 may be easily separated. There may be no residue of the second adhesive layer 130B remaining on the bottom surface of the first redistribution substrate 500. The bottom surface of the first redistribution substrate 500 may include bottom surfaces of the under bump seed patterns 525 and a bottom surface of the lowermost first insulating layer 501.

Referring to FIG. 3J, the under bump seed patterns 525 may be removed to expose bottom surfaces of the under bump patterns 520.

Referring to FIG. 3K, solder terminals 700 may be formed on the bottom surfaces of the under bump patterns 520. Forming the solder terminals 700 may include arranging the solder terminals 700 on the bottom surfaces of the under bump patterns 520 and performing a reflow process. The reflow process of the solder terminals 700 may correspond to the heat treatment subprocess described in the example of FIG. 2C. The reflow process of the solder terminals 700 may be performed at about 150° C. to about 280° C. Because the second support tape 12 has improved thermal insulation properties, deformation of the second support tape 12 may be prevented during the reflow process of the solder terminals 700. As a result of the reflow process, the solder terminals 700 may be bonded to the corresponding under bump patterns 520 and may be electrically connected to the under bump patterns 520. Accordingly, the solder terminals 700 may be electrically connected to the first redistribution substrate 500. The solder terminals 700 may include solder balls.

Referring to FIG. 3L, a sawing process may be performed on a bottom surface of the preliminary semiconductor package PP to form grooves 900. The grooves 900 may pass through the first redistribution substrate 500, the molding layer 400, and the second redistribution substrate 600. A plurality of semiconductor packages PKG may be formed from the preliminary semiconductor package PP by the grooves 900. The plurality of semiconductor packages PKG may be separated from one another by the grooves 900. The grooves 900 may surround the plurality of semiconductor packages PKG in a plan view. The grooves 900 may expose the second support tape 12.

Each of the plurality of semiconductor packages PKG may include a first redistribution substrate 500, at least one semiconductor chip 200, bumps 250, an underfill layer 410, conductive posts 300, a molding layer 400, and a second redistribution substrate 600.

Referring to FIG. 3M, the plurality of semiconductor packages PKG may be separated from the second support tape 12. Separating the plurality of semiconductor packages PKG from the second support tape 12 may include irradiating light to cure the second adhesive layer 130B and applying tensile force to the second support tape 12. Light may be irradiated to the second support tape 12 to cure the second adhesive layer 130B. Adhesive force between the semiconductor device 20 and the cured second adhesive layer 130B may be reduced.

Tensile force may be applied to the second support tape 12 by pulling the second frame 32 outward. Because the second support tape 12 is stretched laterally, the plurality of semiconductor packages PKG may be separated from the second support tape 12. Because each of the first aerogel layer 111B and the second aerogel layer 112B has a relatively high elongation yield, the plurality of semiconductor packages PKG may be easily separated from the second support tape 12. Thereafter, the plurality of semiconductor packages PKG may be picked up. Pick-up characteristics of the plurality of semiconductor packages PKG may be improved. Because each of the first aerogel layer 111B and the second aerogel layer 112B has a relatively high elongation yield, the plurality of semiconductor packages PKG may be easily separated from the second support tape 12. For example, after the plurality of semiconductor packages PKG are separated from the second support tape 12, no residue of the second adhesive layer 130B may remain on top surfaces of the plurality of semiconductor packages PKG. The top surfaces of the plurality of semiconductor packages PKG may be attached to the second adhesive layer 130B. Manufacturing of the plurality of semiconductor packages PKG may be completed by the examples described so far.

While the inventive concept has been particularly shown and described with reference to embodiments thereof, it will be understood that various changes in form and details may be made therein without departing from the spirit and scope of the following claims.

What is claimed is:

1. A semiconductor device manufacturing support tape comprising:
a base layer including a first aerogel layer; and
an adhesive layer on a top surface of the first aerogel layer, wherein a bottom surface of the first aerogel layer is externally exposed.

2. The semiconductor device manufacturing support tape of claim 1, wherein the first aerogel layer has a thermal conductivity of about 0.00001 W/mK to about 0.03 W/mK, and
wherein the first aerogel layer has an elongation yield of about 50% to about 1,500%.

3. The semiconductor device manufacturing support tape of claim 1, wherein the base layer further comprises:
a second aerogel layer on the top surface of the first aerogel layer; and
a polymer layer between the first aerogel layer and the second aerogel layer.

4. The semiconductor device manufacturing support tape of claim 3, wherein the first aerogel layer has a thickness of about 25 μm to about 100 μm, wherein the second aerogel layer has a thickness of about 25 μm to about 100 μm, and
wherein the polymer layer has a thickness of about 25 μm to about 100 μm.

5. The semiconductor device manufacturing support tape of claim 1, wherein the base layer further comprises a polymer layer between the first aerogel layer and the adhesive layer, and
wherein the adhesive layer is attached to the polymer layer.

6. The semiconductor device manufacturing support tape of claim 5, further comprising an adhesive film between the first aerogel layer and the polymer layer, wherein a thickness of the adhesive film is less than a thickness of the first aerogel layer and the thickness of the adhesive film is less than a thickness of the polymer layer.

7. The semiconductor device manufacturing support tape of claim 1, wherein the base layer has a thickness of about 25 μm to about 300 μm, and
wherein the base layer has a thermal conductivity of about 0.001 W/mK to about 0.005 W/mK.

8. The semiconductor device manufacturing support tape of claim 1, further comprising a cover film on a top surface of the adhesive layer.

9. The semiconductor device manufacturing support tape of claim 1, wherein the first aerogel layer has a density of about 500 g/m³ to about 1,500 g/m³, wherein the first aerogel layer has pores therein, and
wherein the first aerogel layer has a porosity of about 90 vol % to about 99.8 vol %.

10. A semiconductor device manufacturing support tape comprising:
a first aerogel layer; and
an adhesive layer on a top surface of the first aerogel layer, wherein a bottom surface of the first aerogel layer is externally exposed, wherein the first aerogel layer has a thermal conductivity of about 0.00001 W/mK to about 0.03 W/mK, wherein the first aerogel layer has an elongation yield of about 50% to about 1,500%, wherein the first aerogel layer has a density of about 500 g/m³ to about 1,500 g/m³, wherein the first aerogel layer has pores therein, and
wherein the first aerogel layer has a porosity of about 90 vol % to about 99.8 vol %.

11. The semiconductor device manufacturing support tape of claim 10, further comprising a polymer layer provided between the first aerogel layer and the adhesive layer and
wherein the polymer layer has a thickness of about 25 μm to about 100 μm.

12. The semiconductor device manufacturing support tape of claim 11, further comprising a second aerogel layer between the polymer layer and the adhesive layer, wherein the second aerogel layer has a thermal conductivity of about 0.00001 W/mK to about 0.03 W/mK,
wherein the second aerogel layer has an elongation yield of about 50% to about 1,500%, wherein the second aerogel layer has a density of about 500 g/m³ to about 1,500 g/m³, wherein the second aerogel layer has pores therein, and
wherein the second aerogel layer has a porosity of about 90 vol % to about 99.8 vol %.

13. A semiconductor device manufacturing method comprising:
providing a support tape including a base layer and an adhesive layer;
providing a preliminary semiconductor device on the adhesive layer;
performing a processing step on the preliminary semiconductor device to form a semiconductor device; and
separating the semiconductor device from the support tape, wherein the base layer comprises a first aerogel layer.

14. The semiconductor device manufacturing method of claim 13, wherein the separating of the preliminary semiconductor device from the support tape comprises applying a tensile force to the support tape, and
wherein the first aerogel layer has an elongation yield of about 50% to about 1,500%.

15. The semiconductor device manufacturing method of claim 14, further comprising attaching a frame onto an edge region of a top surface of the adhesive layer, wherein the preliminary semiconductor device is provided on the top surface of the adhesive layer and is apart from the frame, and
wherein the applying of the tensile force comprises pulling the frame outward.

16. The semiconductor device manufacturing method of claim 13, wherein the processing step comprises a heat treatment subprocess, and
wherein the first aerogel layer has a thermal conductivity of about 0.00001 W/mK to about 0.03 W/mK.

17. The semiconductor device manufacturing method of claim 16, wherein the heat treatment subprocess comprises at least one of:
a reflow operation of solder balls;
a thermal curing operation of an underfill layer; and
a curing operation of a molding layer.

18. The semiconductor device manufacturing method of claim 13, wherein the base layer further comprises:
a second aerogel layer on the first aerogel layer; and
a polymer layer between the first aerogel layer and the second aerogel layer, and
wherein the adhesive layer is attached to the polymer layer.

19. The semiconductor device manufacturing method of claim 18, wherein the second aerogel layer has a thermal conductivity of about 0.00001 W/mK to about 0.03 W/mK, and
wherein the second aerogel layer has an elongation yield of about 50% to about 1,500%.

20. The semiconductor device manufacturing method of claim 13, wherein the preliminary semiconductor device comprises a wafer-level preliminary semiconductor device.
